(19) United States
(12) Patent Application Publication
(10) Pub. No.: US 2026/0143841 A1
(43) Pub. Date: May 21, 2026

(54) IMAGE SENSOR AND METHOD OF FABRICATING THE SAME

(71) Applicant: Samsung Electronics Co., Ltd., Suwon-si (KR)

(72) Inventor: Kook Tae KIM, Suwon-si (KR)

(73) Assignee: Samsung Electronics Co., Ltd., Suwon-si (KR)

(21) Appl. No.: 19/236,207

(22) Filed: Jun. 12, 2025

(30) Foreign Application Priority Data
Nov. 21, 2024 (KR) 10-2024-0167603

(51) Int. Cl. H10F 39/00

(52) U.S. Cl. CPC H10F 39/807; H10F 39/8053; H10F 39/8057; H10F 39/811

(57) ABSTRACT

An image sensor may include a semiconductor substrate in which photoelectric converters are defined, color filters on the semiconductor substrate, and grid structures between color filters. The grid structures each may include a gap insulating layer surrounding a fence gap defined by the gap insulating layer, and a supporter on the gap insulating layer. The fence gap may include a gap upper curved surface, first and second sidewalls extending from the gap upper curved surface toward the semiconductor substrate, and a lower surface including a flat surface between the first sidewall and the second sidewall. The gap insulating layer may completely cover the gap upper curved surface and the first and second sidewalls of the fence gap. The gap insulating layer may cover 50% or more of the lower surface of the fence gap. The supporter may be spaced apart from the fence gap.

### CROSS-REFERENCE TO RELATED APPLICATIONS

This U.S. non-provisional patent application claims priority under 35 U.S.C. § 119 to Korean Patent Application No. 10-2024-0167603 filed on Nov. 21, 2024, in the Korean Intellectual Property Office, the entire contents of which are hereby incorporated by reference.

### BACKGROUND

Inventive concepts relate to an image sensor and a method of fabricating the same, and more specifically, relates to a CMOS image sensor and a method of fabricating the same.

An image sensor is a semiconductor device that converts an optical image into an electrical signal. Recently, with the development of the computer industry and the communication industry, the demand for image sensors with improved performance has been increasing in various fields such as digital cameras, camcorders, PCS (Personal Communication Systems), game devices, security cameras, and medical micro cameras.

As semiconductor devices become more highly integrated, image sensors are also becoming more highly integrated. Accordingly, the sizes of each pixel are also becoming smaller. Accordingly, an image sensor with lower crosstalk and/or higher sensitivity in a small region may be advantageous.

### SUMMARY

An aspect of inventive concepts provides an image sensor advantageous for pixel miniaturization and/or a method of fabricating the same.

An aspect of inventive concepts provides an image sensor with improved sensitivity and/or a method of fabricating the same.

An aspect of inventive concepts provides an image sensor with reduced crosstalk by providing a stable and constant grid air gap, and/or a method of fabricating the same.

Aspects of inventive concepts are not limited to the aspects mentioned above, and other aspects not mentioned may be clearly understood by those skilled in the art from the description below.

An image sensor according to some embodiments of inventive concepts may include a semiconductor substrate in which a plurality of photoelectric converters may be defined; a plurality of color filters on the semiconductor substrate; and grid structures between the plurality of color filters, respectively. The grid structures each may include a gap insulating layer surrounding a fence gap defined by the gap insulating layer and a supporter on the gap insulating layer. The fence gap may include a gap upper curved surface, a first sidewall extending from the gap upper curved surface toward the semiconductor substrate, a second sidewall opposite the first sidewall, and a lower surface. The lower surface of the fence gap may include a flat surface between the first sidewall of the fence gap and the second sidewall of the fence gap. The gap insulating layer may completely cover the gap upper curved surface of the fence gap, the first sidewall of the fence gap, and the second sidewall of the fence gap. The gap insulating layer may cover 50% or more of the lower surface of the fence gap. The supporter may be spaced apart from the fence gap.

An image sensor according to some embodiments of inventive concepts may include a semiconductor substrate in which a plurality of photoelectric converters are defined; a plurality of color filters on the semiconductor substrate; and grid structures between the plurality of color filters, respectively. The grid structures may include grid structures of an intervention region on the semiconductor substrate and grid structures of an intersection region on the semiconductor substrate. The grid structures of the intervention region and the grid structures of the intersection region each may include a gap insulating layer surrounding a fence gap defined by the gap insulating layer and a supporter on the gap insulating layer. The fence gap may include a gap upper curved surface, a first sidewall extending from the gap upper curved surface toward the semiconductor substrate, a second sidewall opposite the first sidewall, and a lower surface. The lower surface of the fence gap may include a flat surface between the first sidewall of the fence gap and the second sidewall of the fence gap. The gap insulating layer may completely cover the gap upper curved surface of the fence gap, the first sidewall of the fence gap, and the second sidewall of the fence gap. The gap insulating layer covers 50% or more of the lower surface of the fence gap. The grid structures of the intersection region may be spaced apart from each other.

An image sensor according to some embodiments of inventive concepts may include a semiconductor substrate in which a plurality of photoelectric converters are defined, wherein a first surface of the semiconductor substrate may be opposite a second surface of the semiconductor substrate; a transfer gate on the first surface of the semiconductor substrate; a fixed charge layer on the second surface of the semiconductor substrate; a protective layer on the fixed charge layer; a backside insulating layer on the protective layer; a capping layer on the backside insulating layer; a plurality of color filters on the capping layer; and grid structures between the plurality of color filters, respectively. The grid structures each may include a gap insulating layer surrounding a fence gap defined by the gap insulating layer and a supporter on the gap insulating layer. The fence gap may include a gap upper curved surface, a first sidewall extending from the gap upper curved surface toward the semiconductor substrate, a second sidewall opposite the first sidewall, and a lower surface. The lower surface of the fence gap may include a flat surface between the first sidewall of the fence gap and the second sidewall of the fence gap. The gap insulating layer may completely cover the gap upper curved surface of the fence gap, the first sidewall of the fence gap, and the second sidewall of the fence gap. The gap insulating layer may cover 50% or more of a lower surface of the fence gap. The supporter may be spaced apart from the fence gap.

According to some embodiments of inventive concepts, a method of fabricating an image sensor may include forming grid structures on a semiconductor substrate in which a plurality of photoelectric converters may be defined; and forming a plurality of color filters on the semiconductor substrate between the grid structures. The grid structures each may include a gap insulating layer surrounding a fence gap defined by the gap insulating layer and a supporter on the gap insulating layer. The fence gap may include a gap upper curved surface, a first sidewall extending from the gap upper curved surface toward the semiconductor substrate, a second sidewall opposite the first sidewall, and a lower surface. The lower surface of the fence gap may include a flat surface between the first sidewall of the fence gap and the second sidewall of the fence gap. The gap insulating layer may completely cover the gap upper curved surface of the fence gap, the first sidewall of the fence gap, and the second sidewall of the fence gap. The gap insulating layer may cover 50% or more of the lower surface of the fence gap. The supporter may be spaced apart from the fence gap.

In some embodiments, the method may further include forming a capping layer over the grid structures and the semiconductor substrate before the forming the plurality of color filters on the semiconductor substrate between the grid structures.

In some embodiments, the method may further include forming a shield layer over the grid structures and the semiconductor substrate before the forming the plurality of color filters on the semiconductor substrate between the grid structures.

In some embodiments, the method may further include forming a fixed charge layer on the semiconductor substrate; forming a protective layer on the fixed charge layer such that the fixed charge layer is between the semiconductor substrate and the protective layer; and forming a backside insulating layer on the protective layer. The forming the grid structures on the semiconductor substrate may be performed after the forming the backside insulating layer and the grid structures are formed on the backside insulating layer.

In some embodiments, the method may further include forming a conductive member through the protective layer and the backside insulating layer before the grid structures are formed on the backside insulating layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of an image sensor according to some embodiments of inventive concepts.

FIG. 2 is a cross-sectional view taken along line A-A′ of FIG. 1.

FIG. 3 is a cross-sectional view taken along line B-B′ of FIG. 1.

FIG. 4 is an enlarged cross-sectional view of ‘M’ of FIG. 2.

FIG. 5 is an enlarged cross-sectional view of ‘N’ of FIG. 3.

FIGS. 6, 16, and 18 are views showing image sensors according to some embodiments, and are cross-sectional views corresponding to the enlarged cross-sectional view of ‘M’ in FIG. 2.

FIGS. 7, 17, and 19 are views showing image sensors according to some embodiments, and are cross-sectional views corresponding to the enlarged cross-sectional view of ‘N’ in FIG. 3.

FIGS. 8, 10, 12, 14, 16, and 18 are views showing image sensors according to some embodiments, and are cross-sectional views corresponding to the enlarged cross-sectional view of ‘X’ in FIG. 2.

FIGS. 9, 11, 13, 15, 17, and 19 are views showing image sensors according to some embodiments, and are cross-sectional views corresponding to the enlarged cross-sectional view of ‘Y’ in FIG. 3.

FIGS. 20, 22, 24, 26, 28, 30, 32, 34, 36, 38, 40, 42, 44, 46, 48, 50, and 52 are enlarged views corresponding to the enlarged view of ‘Q’ in FIG. 2, which illustrate a method of fabricating an image sensor according to some embodiments of inventive concepts.

FIGS. 21, 23, 25, 27, 29, 31, 33, 35, 37, 39, 41, 43, 45, 47, 49, 51 and 53 are enlarged views corresponding to the enlarged view of ‘R’ in FIG. 2, which illustrate a method of fabricating an image sensor according to some embodiments of inventive concepts.

### DETAILED DESCRIPTION

Hereinafter, inventive concepts will be described in detail by describing embodiments of inventive concepts with reference to the attached drawings.

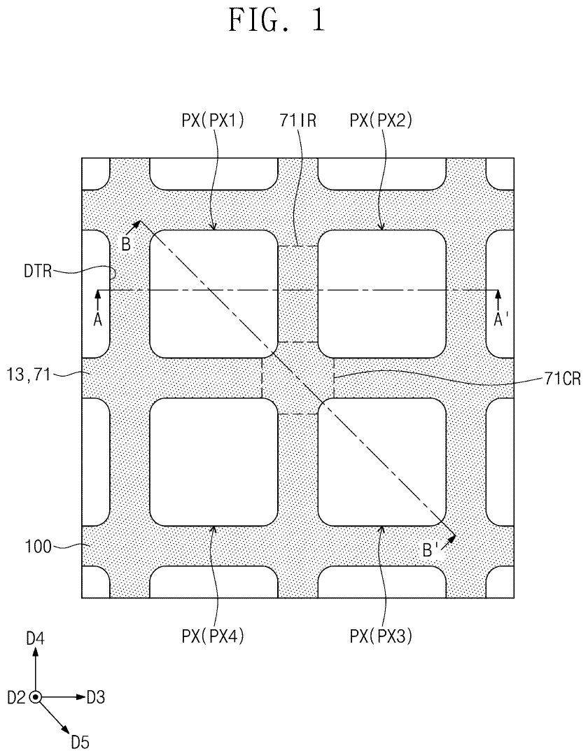

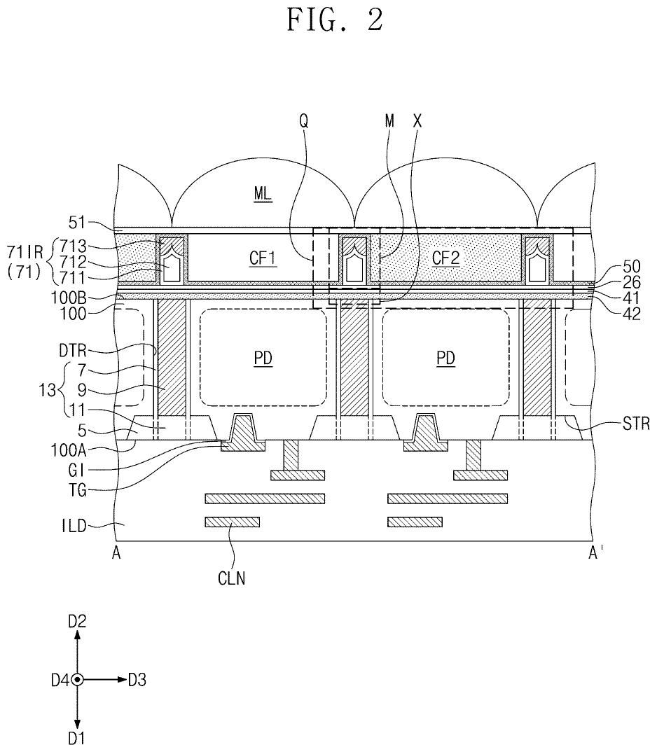

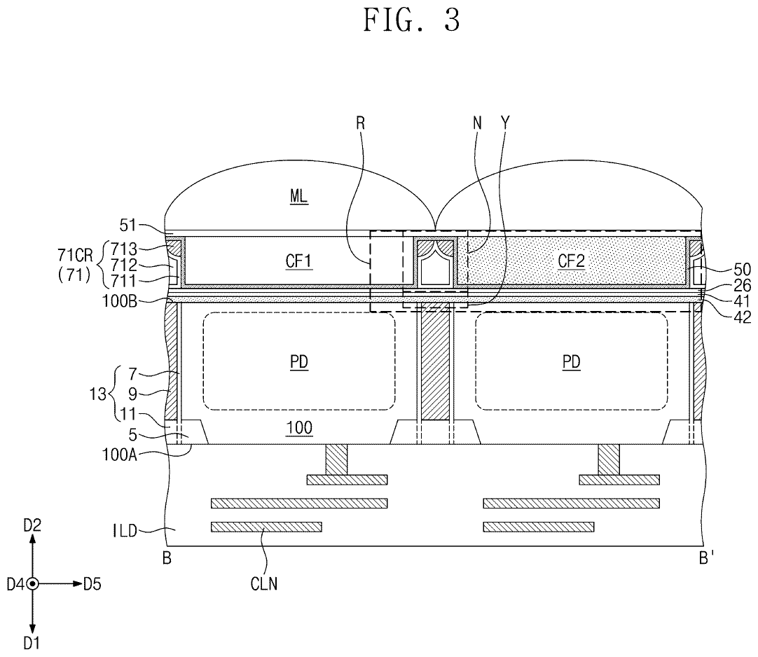

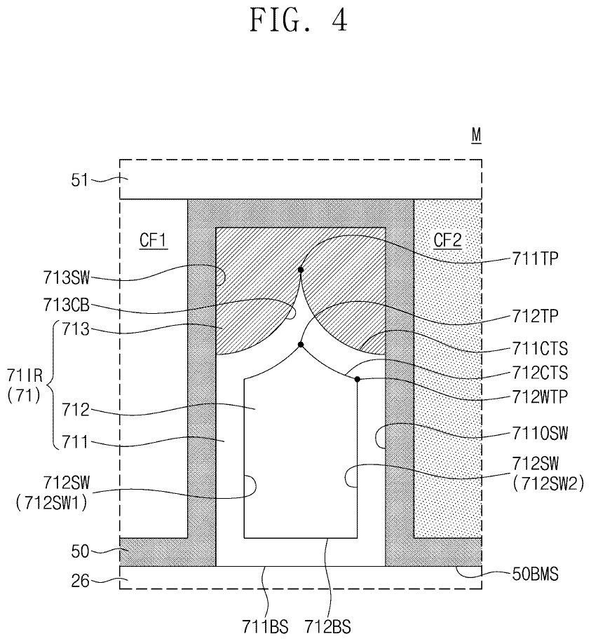

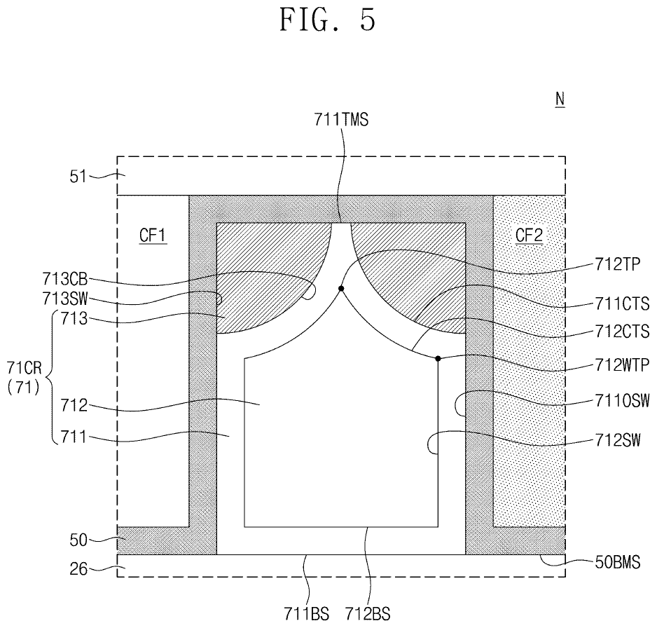

FIG. 1 is a plan view of an image sensor according to some embodiments of inventive concepts. FIG. 2 is a cross-sectional view taken along line A-A′ of FIG. 1. FIG. 3 is a cross-sectional view taken along line B-B′ of FIG. 1. FIG. 4 is an enlarged cross-sectional view of ‘M’ of FIG. 2. FIG. 5 is an enlarged cross-sectional view of ‘N’ of FIG. 3.

Referring to FIGS. 1, 2, 3, and 4, a substrate 100 may be provided. The substrate 100 may be, for example, a silicon single crystal wafer, a silicon epitaxial layer, or a silicon on insulator (SOI) substrate. For example, the substrate 100 may be doped with an impurity having a first conductivity type (e.g., P type). The substrate 100 may include a first surface 100A and a second surface 100B that may be opposite each other. The first surface 100A may be spaced apart from the second surface 100B in a first direction D1. The second surface 100B may be spaced apart from the first surface 100A in a second direction D2.

The image sensor according to inventive concepts may include a plurality of pixel regions PX. For example, pixel regions PX may include first, second, third, and fourth pixel regions PX1, PX2, PX3, and PX4 that are disposed in sequence in a clockwise direction. The first and second pixel regions PX1 and PX2 may be arranged side surface by side surface in a third direction D3, and the third and fourth pixel regions PX3 and PX4 may also be arranged side surface by side surface in the third direction D3. The third direction D3 may be a direction parallel to the second surface 100B of the substrate 100. The second and third pixel regions PX2 and PX3 may be arranged side surface by side surface in a fourth direction D4, and the first and fourth pixel regions PX1 and PX4 may also be arranged side surface by side surface in the fourth direction D4. The fourth direction D4 may be a direction parallel to the second surface 100B of the substrate 100 and intersecting the third direction D3.

A device separation pattern 13 may be disposed in a separation trench DTR extending from the first surface 100A toward the second surface 100B. When viewed in a plan view, the device separation pattern 13 may have a mesh shape in which lines extending in the third and fourth directions D3 and D4 intersect.

The device separation pattern 13 may be disposed on a first substrate 1 to separate photoelectric converters PD. The photoelectric converter PD may be doped with an impurity of a second conductivity type opposite to the first conductivity type, for example. The second conductivity type may be, for example, N type. An N type impurity region formed by doping in the photoelectric converter PD may form a PN junction with a P type impurity region of an adjacent substrate 100 to provide a photodiode.

A grid structure 71 may be disposed to overlap the device separation pattern 13 in the second direction D2. The grid structure 71 may include a grid structure 71IR of an intervention region IR and a grid structure 71CR of an intersection region CR.

The grid structure 71 may include a fence gap 712 defined by a gap insulating layer 711, a gap insulating layer 711 surrounding the fence gap 712, and a supporter 713 disposed on the gap insulating layer 711. The supporter 713 may be spaced apart from the fence gap 712.

A capping layer 50 may be provided on the grid structure 71. The capping layer 50 may surround an upper surface and side surfaces of the grid structure 71. The capping layer 50 may be contact with color filters CF1 and CF2. The capping layer 50 may include a metal oxide or silicon. The capping layer 50 may include at least one of a single layer of a metal oxide such as Al₂O₃, a multi-layer of silicon oxide/Al₂O₃, or a single layer or multi-layer of TiO₂, Ta₂O₅, Ta₂O₃, HfO, ZrO, Si₃N₄, SiCN, etc.

The grid structure 71IR of the intervention region IR may be defined as a grid structure that overlaps a region between two adjacent pixel regions PX. An intersection region CR may be defined as a grid structure that overlaps a region between four adjacent pixel regions PX. The intervention region IR and the intersection region CR may be continuous.

A shallow device isolation layer 5 may be disposed adjacent to the first surface 100A of the substrate 100. The device separation pattern 13 may penetrate the shallow device isolation layer 5. A shallow device isolation trench STR may be recessed from the first surface 100A of the substrate 100 into the substrate 100, and the shallow device isolation layer 5 may fill the shallow device isolation trench STR. The shallow device isolation layer 5 may be disposed adjacent to the first surface 100A of the substrate 100. The shallow device isolation layer 5 may include a silicon oxide layer inserted into the interior of the substrate from the first surface 100A. As an example, the shallow device isolation layer 5 may include a silicon nitride layer interposed between silicon oxide layers.

The device separation pattern 13 may include a conductive pattern 9 disposed in the separation trench DTR, a separation insulating layer 7 surrounding a side surface of the conductive pattern 9, and a buried insulating pattern 11 interposed between the conductive pattern 9 and the first surface 100A of the substrate 100. The conductive pattern 9 may include a conductive material, for example, polysilicon doped with a metal or impurity. The separation insulating layer 7 may include, for example, a silicon oxide layer. The buried insulating patterns 11 may include, for example, a silicon oxide layer.

Although it is illustrated that there is a boundary between the shallow device isolation layer 5 and the device separation pattern 13, the boundary may not be distinguished between the shallow device isolation layer 5 and the device separation pattern 13. For example, there may be no interface between the shallow device isolation layer 5 and the separation insulating layer 7. In addition, the interface between the separation insulating layer 7 and the buried insulating pattern 11 may not be distinguished.

A transfer gate TG may be provided on the first surface 100A of the substrate 100 in each pixel region PX. For example, a portion of the transfer gate TG may be buried inside the substrate 100. The transfer gate TG may be of a vertical type. For example, a first portion of the transfer gate TG may be provided in the first surface 100A of the substrate 100, and a second portion may be provided on the first surface 100A of the substrate 100. That is, a portion of the transfer gate TG may extend into the substrate 100. The transfer gate TG may be a gate electrode of a transfer transistor.

As another example, the transfer gate TG may be a planar type that is flat on the first surface 100A of the substrate 100.

A gate insulating pattern GI may be interposed between the transfer gate TG and the substrate 100. A floating diffusion region (not shown) may be provided in the substrate 100 adjacent to one side surface of the transfer gate TG. For example, an impurity having a second conductivity type may be doped into the floating diffusion region (not shown).

According to some embodiments of inventive concepts, light may be incident into the interior of the substrate 100 through the second surface 100B of the substrate 100. Electron-hole pairs may be generated at the PN junction by the incident light. The electrons thus generated may move to the photoelectric converter PD. The electrons may move to a floating diffusion region (not shown) as voltage is applied to the transfer gate TG.

An interlayer insulating layer ILD may be provided on the first surface 100A of the substrate 100 and may cover the first surface 100A. The interlayer insulating layer ILD may be a composite layer including at least one of a silicon oxide layer, a silicon nitride layer, a silicon oxynitride layer, a porous low-k dielectric layer, or a combination thereof. Wirings CLN may be provided in the interlayer insulating layer ILD. A floating diffusion region (not shown) may be connected to the wirings CLN.

A fixed charge layer 42 may be provided on the second surface 100B of the substrate 100 and may cover the second surface 100B. The fixed charge layer 42 may be a single layer or a composite layer including at least one of a metal oxide layer or a metal fluoride layer, each containing oxygen or fluorine in an amount less than the stoichiometric ratio, or a combination thereof. As a result, the fixed charge layer 42 may have a negative fixed charge. For example, the fixed charge layer 42 may include a metal oxide layer or a metal fluoride layer including at least one of hafnium (Hf), zirconium (Zr), aluminum (Al), tantalum (Ta), titanium (Ti), yttrium (Y), or lanthanide, or a combination thereof. The fixed charge layer 42 may improve dark current and/or white spots.

A protective layer 41 may be provided on the fixed charge layer 42. The protective layer 41 may be a bottom antireflective coating (BARC) layer. The protective layer 41 may include a single layer or a multilayer layer. The protective layer 41 may include an insulating material having high transmittance. For example, the protective layer 41 may include silicon oxide. For example, the protective layer 41 may include PEOx.

A backside insulating layer 26 may be provided on the protective layer 41. The backside insulating layer 26 may cover the protective layer 41. For example, the backside insulating layer 26 may include aluminum oxide. For example, the backside insulating layer 26 may be a metal oxide layer including at least one of hafnium (Hf), zirconium (Zr), aluminum (Al), tantalum (Ta), titanium (Ti), yttrium (Y), or lanthanide, or a combination thereof.

Grid structures 71 may be disposed on the second surface 100B of the substrate 100. The grid structures 71 overlap the device separation pattern 13 and may have a grid shape when viewed in a plan view. The grid structures 71 may have a refractive index lower than that of color filters CF1 and CF2 described below. The grid structures 71 may limit and/or prevent crosstalk between adjacent pixel regions PX.

The color filters CF1 and CF2 may be disposed between adjacent grid structures 71. The color filters CF1 and CF2 may each have one color among blue, green, and red. As another example, the color filters CF1 and CF2 may include other colors such as cyan, magenta, or yellow. In the image sensor according to the present example, the color filters CF1 and CF2 may be disposed in a Bayer pattern form. In another example, the color filters CF1 and CF2 may be disposed in a Tetra pattern form in a 2×2 array, a nona pattern form in a 3×3 array, or a hexadeca pattern form in a 4×4 array.

A backside protective layer 51 may be disposed on the color filters CF1 and CF2. The backside protective layer 51 may include an insulating material.

Micro lenses ML may be disposed on the backside protective layer 51. Edges of the micro lenses ML may be in contact with each other and may be connected to each other.

In addition to the photoelectric converter PD and the transfer gate TG, although not shown, a gate electrode of a reset transistor, a gate electrode of a source follower transistor, and a gate electrode of a selection transistor may be provided on the first surface 100A of the substrate 100. The photoelectric converter PD and the transistors may constitute a unit pixel. Alternatively, a gate electrode of the reset transistor, a gate electrode of the source follower transistor, and a gate electrode of the selection transistor may be provided on an additional substrate other than the substrate 100.

Referring again to FIGS. 4 and 5, the grid structure 71 is illustrated in more detail. A sidewall and an upper surface of the grid structure 71 may be in contact with the capping layer 50. A sidewall 713SW of the supporter 713 and an outer sidewall 7110SW of the gap insulating layer 711 may be in contact with the capping layer 50.

The fence gap 712 may be defined as a portion surrounded by the gap insulating layer 711. The fence gap 712 may be defined as a vacancy surrounded by the gap insulating layer 711. The fence gap 712 may be, for example, an air gap. A lower surface 712BS of the fence gap 712 may be in contact with the gap insulating layer 711. A level of the lower surface 712BS of the fence gap 712 may be higher than a level of the lowermost surface 50BMS of the capping layer 50.

A lower surface 711BS of the gap insulating layer 711 may be in contact with the backside insulating layer 26. The lower surface 711BS of the gap insulating layer 711 may be substantially the same as a level of the lowermost surface 50BMS of the capping layer 50.

A gap top point 712TP defined at a top of the fence gap 712 may be disposed at a level between a top surface of the supporter and a top point 712WTP of a sidewall 712SW of the fence gap 712.

The fence gap 712 may include a gap upper curved surface 712CTS that is in contact with the gap insulating layer 711 and has a curved surface. The fence gap 712 may have sidewalls 712SW1 and 712SW2 of the fence gap 712 that have a flat surface and extend in the second direction D2. The sidewalls 712SW1 and 712SW2 of the fence gap 712 may extend from the gap upper curved surface 712CTS toward the substrate 100. The substrate 100 may be a semiconductor substrate. The fence gap 712 may have a first sidewall 712SW1 that is in contact with the gap insulating layer 711 and a second sidewall 712SW2 that may be opposite first sidewall 712SW1. The fence gap 712 may have the lower surface 712BS of the fence gap 712 that is in contact with the gap insulating layer 711, has a flat surface, and extends in the third direction D3. The lower surface 712BS of the fence gap 712 may include a flat surface between the first sidewall 712SW1 and the second sidewall 712SW2.

The gap insulating layer 711 may cover the gap upper curved surface 712CTS, the first sidewall 712SW1, and the first sidewall 712SW1 of the fence gap 712. The gap insulating layer 711 may completely cover the gap upper curved surface 712CTS, the first sidewall 712SW1, and the first sidewall 712SW1 of the fence gap 712. The gap insulating layer 711 may cover the lower surface 712BS of the fence gap 712. For example, the gap insulating layer 711 may cover the lower surface 712BS of the fence gap 712 by 50% or more. For example, the gap insulating layer 711 may cover the lower surface 712BS of the fence gap 712 by 80% or more. For example, the gap insulating layer 711 may completely cover the lower surface 712BS of the fence gap 712.

A lower surface of the gap insulating layer 711 facing the upper surface of the fence gap 712 may be curved. The gap upper curved surface 712CTS may have a shape that protrudes toward the fence gap 712. A top point of the fence gap 712 may be defined as the gap top point 712TP. A level of the gap top point 712TP may be higher than a level of a top point 712WTP of a sidewall 712SW of the fence gap 712.

The gap upper curved surface 712CTS may extend from the gap top point 712TP to the top point 712WTP of the sidewall of the fence gap. The sidewall 712SW of the fence gap 712 may be coplanar with the gap insulating layer 711.

A lower surface 713CB of the supporter 713 may include a curved surface. The supporter 713 may have, for example, a fan-shaped shape facing the fence gap 712. An upper surface of the gap insulating layer 711 in contact with the supporter 713 may be a gap insulating layer curved surface 711CTS. The gap insulating layer curved surface 711CTS may be defined as the lower surface 713CB of the supporter 713 in contact with the gap insulating layer 711.

The gap insulating layer 711 may include a metal oxide. The gap insulating layer 711 may include one or more of Al₂O₃, SiO₂, TiO₂, Ta₂O₅, Ta₂O₃, HfO, ZrO, Si₃N₄, or SiCN.

The supporter 713 may include a silicon oxide layer or a silicon nitride layer. The supporter 713 may include Si₃N₄, SiCN, SiOCN, SiBN, or SiBCN.

Referring again to FIG. 4, the grid structure 71IR of the intervention region is illustrated in more detail. The supporter 713 of the grid structure 71IR of the intervention region may be in an integral form. The gap insulating layer 711 of the grid structure 71IR of the intervention region may include a top point 711TP of a gap insulating layer 711. A surface extending from the top point 711TP of the gap insulating layer 711 to the outer wall 7110SW of the gap insulating layer 711 may be defined as a gap insulating layer curved surface 711CTS. The gap insulating layer curved surface 711CTS may be coplanar (e.g., conformal) with the lower surface 713CB of the supporter 713.

Referring again to FIG. 5, the grid structure 71CR of the intersection region is illustrated in more detail. The supporter 713 of the grid structure 71CR of the intersection region may be spaced apart by a gap insulating layer 711. The gap insulating layer 711 may be interposed between adjacent grid structures 71CR spaced apart from each other, and the top surface 711TMS of the gap insulating layer 711 may be in contact with the capping layer 50.

As described above, the grid structure 71 may include a fence gap 712 therein. Accordingly, crosstalk between color filters CF may be limited and/or suppressed, and a constant fence gap 712 may be formed.

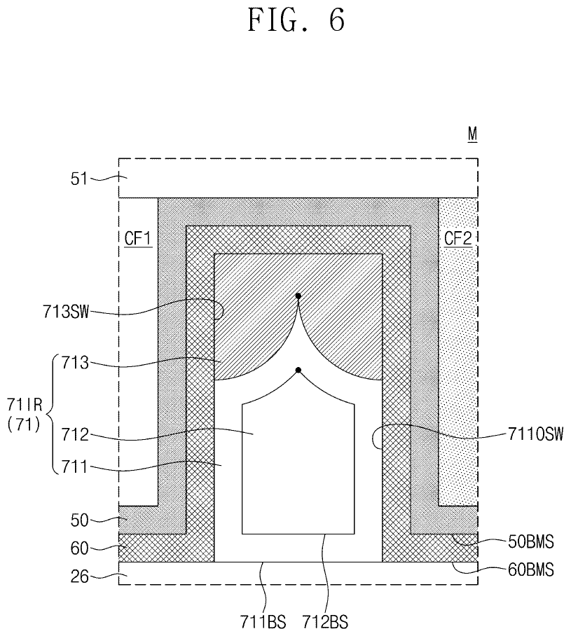

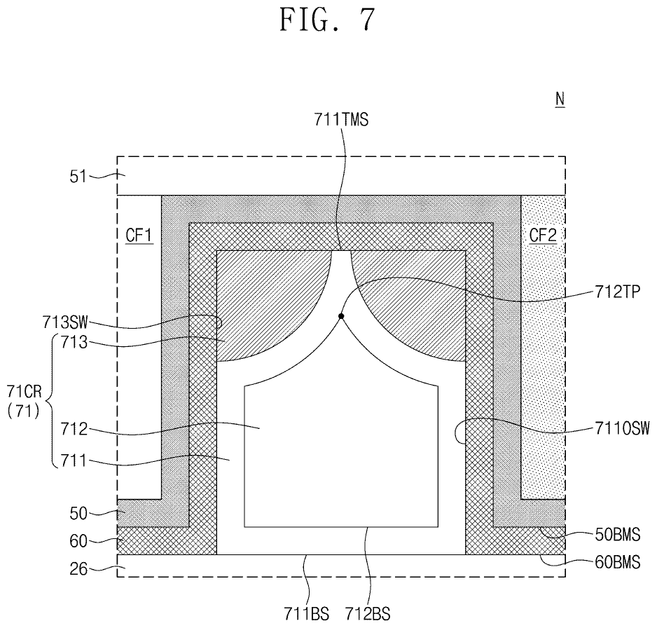

FIGS. 6, 16, and 18 are cross-sectional views corresponding to an enlarged cross-sectional view of M in FIG. 2, illustrating an image sensor according to some embodiments. FIGS. 7, 17, and 19 are cross-sectional views corresponding to an enlarged cross-sectional view of N in FIG. 3, illustrating an image sensor according to some embodiments.

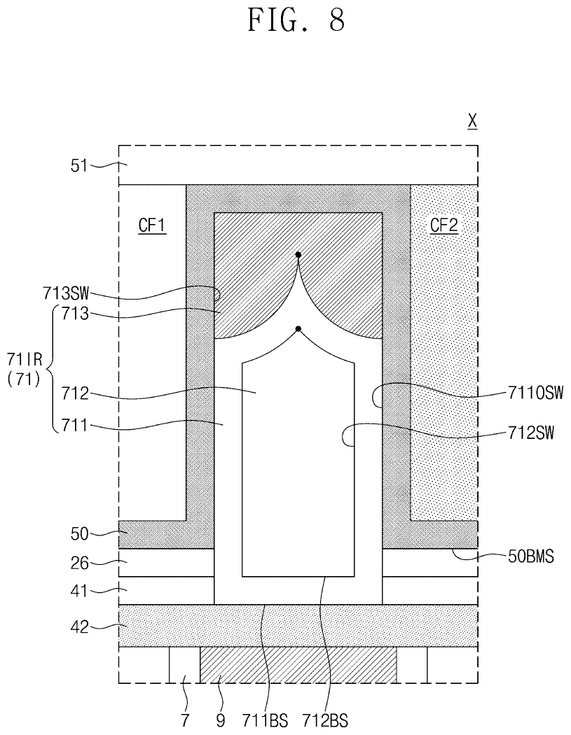

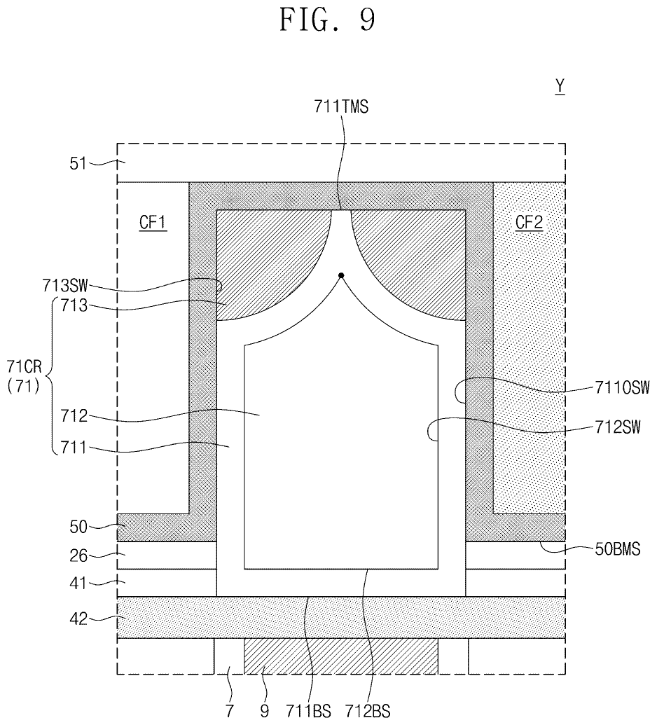

FIGS. 8, 10, 12, 14, 16, and 18 are views showing image sensors according to some embodiments, and are cross-sectional views corresponding to the enlarged cross-sectional view of ‘X’ in FIG. 2. FIGS. 9, 11, 13, 15, 17, and 19 are views showing image sensors according to some embodiments, and are cross-sectional views corresponding to the enlarged cross-sectional view of ‘Y’ in FIG. 3.

For the sake of simplicity, descriptions that are redundant in FIGS. 1 to 5 are omitted.

Referring to FIGS. 6 and 7, a shield layer 60 may be provided below a capping layer 50. The shield layer 60 may surround an upper surface and side surfaces of the grid structure 71. The shield layer 60 may cover the backside insulating layer 26. The capping layer 50 may cover the upper surface of the shield layer 60. The shield layer 60 may include silicon oxide. The shield layer 60 may include a different material from the capping layer 50.

An outer wall 7110SW of the gap insulating layer 711 and a sidewall 713SW of the supporter 713 may be in contact with the shield layer 60. The upper surface of the supporter 713 may be in contact with the shield layer 60. A level of the lower surface 712BS of the fence gap 712 may be higher than a level of the lowermost surface 60BMS of the shield layer 60. A level of the lower surface 711BS of the gap insulating layer 711 may be the same or substantially the same as a level of the lowermost surface 60BMS of the shield layer 60. A level of the lowermost surface 60BMS of the shield layer 60 may be lower than a level of the lower surface of the capping layer 50.

In the grid structure 71IR of the intervention region, the shield layer 60 may be in contact with the upper surface and side surface of the supporter 713 and may be spaced apart from the upper surface of the gap insulating layer 711.

In the grid structure 71CR of the intersection region, the shield layer 60 may be in contact with the upper surface and side surface of the supporter 713 and may be in contact with the top surface 711TMS of the gap insulating layer 711.

Referring to FIGS. 8 and 9, in some embodiments, the grid structure 71 may penetrate the backside insulating layer 26 and the protective layer 41. The grid structure 71 may be in contact with the fixed charge layer 42.

A level of the lower surface 712BS of the fence gap 712 may be lower than a level of the lowermost surface 50BMS of the capping layer 50. The outer wall 7110SW of the gap insulating layer 711 may be in contact with the capping layer 50, the backside insulating layer 26, and the protective layer 41.

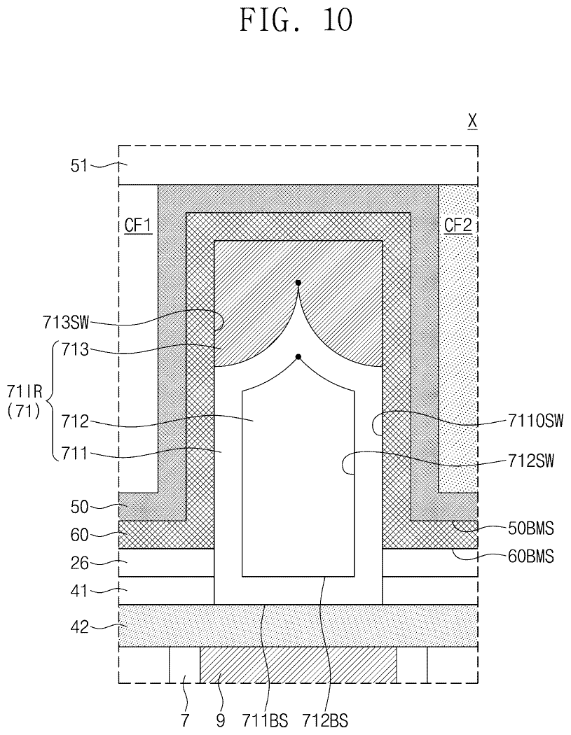

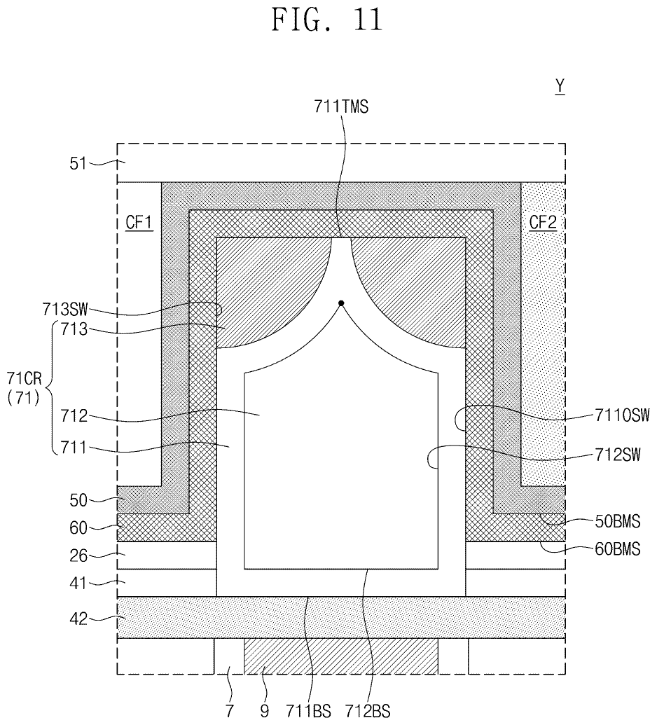

Referring to FIGS. 10 and 11, the grid structure 71 may penetrate the backside insulating layer 26 and the protective layer 41. A shield layer 60 may be provided below the capping layer 50. The grid structure 71 may be in contact with the fixed charge layer 42. A level of the lower surface 712BS of the fence gap 712 may be lower than a level of the lowermost surface 50BMS of the capping layer 50. A level of the lower surface 712BS of the fence gap 712 may be lower than a level of the lowermost surface 60BMS of the shield layer 60. The outer wall 7110SW of the gap insulating layer 711 may be in contact with the shield layer 60, the backside insulating layer 26, and the protective layer 41. A level of the lower surface 711BS of the gap insulating layer 711 may be lower than a level of the lowermost surface 60BMS of the shield layer 60.

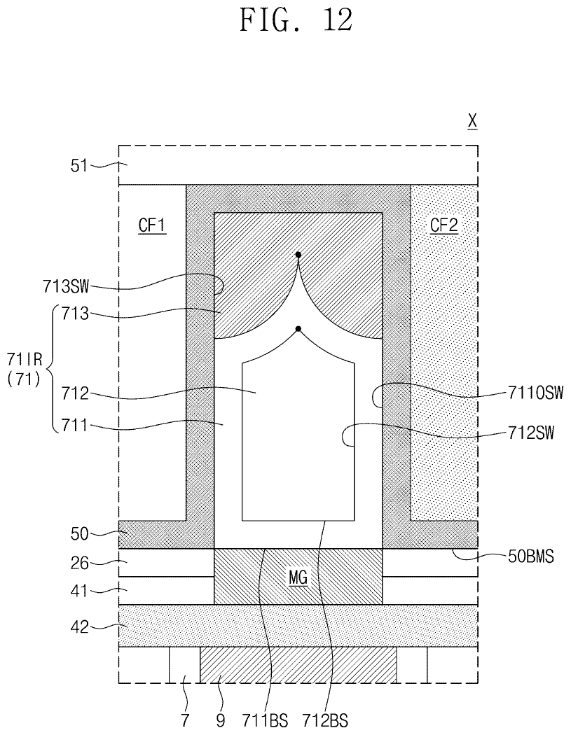

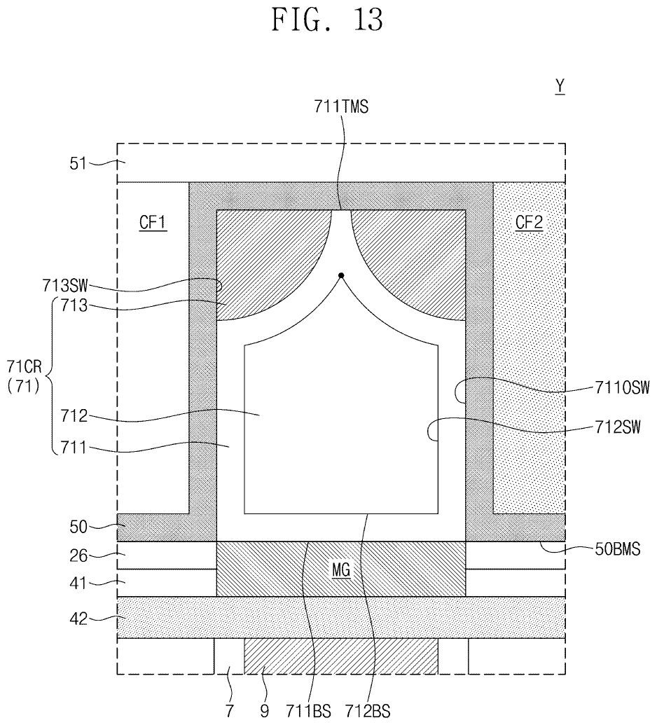

Referring to FIGS. 12 and 13, a conductive member MG may be further provided below the grid structures 71. The conductive member MG may be interposed between the substrate 100 and the gap insulating layer 711. The conductive member MG may be in contact with the fixed charge layer 42. The conductive member MG may be interposed between the fixed charge layer 42 and the gap insulating layer 711. A width of the conductive member MG may be the same or similar to that of the grid structures 71, but is not limited thereto. A sidewall of the conductive member MG may be in contact with the backside insulating layer 26 and the protective layer 41. An upper surface of the conductive member MG may be in contact with the gap insulating layer 711. The conductive member MG may include, for example, TiN, W, or Al.

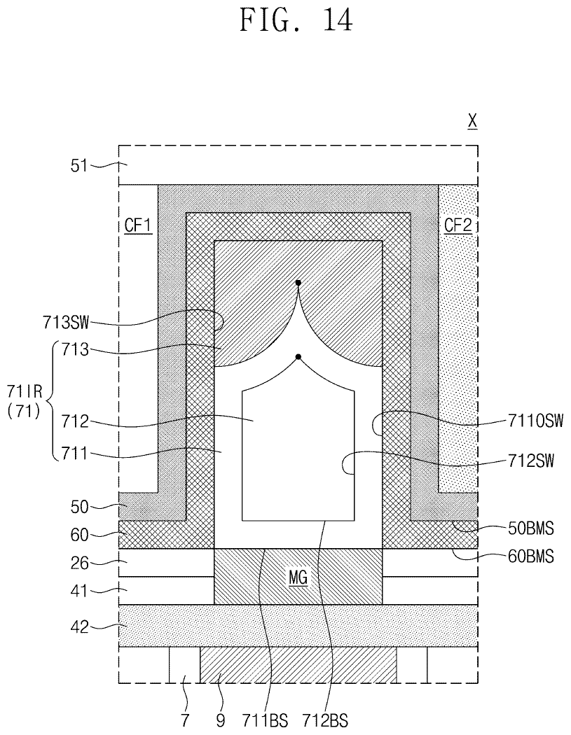

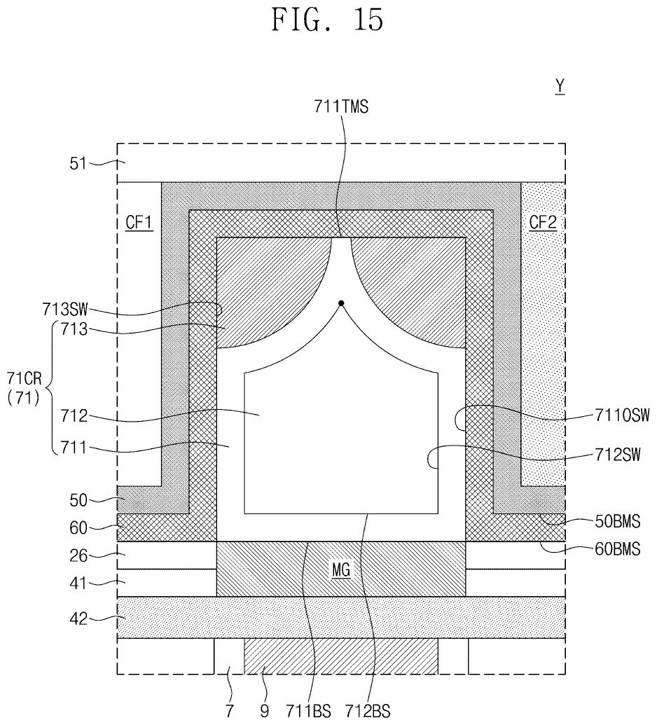

Referring to FIGS. 14 and 15, the conductive member MG may be further provided below the grid structures 71. The conductive member MG may be interposed between the substrate 100 and the gap insulating layer 711. The conductive member MG may be in contact with the fixed charge layer 42. The conductive member MG may be interposed between the fixed charge layer 42 and the gap insulating layer 711. The shield layer 60 may be provided below the capping layer 50. The shield layer 60 may be spaced apart from the conductive member MG.

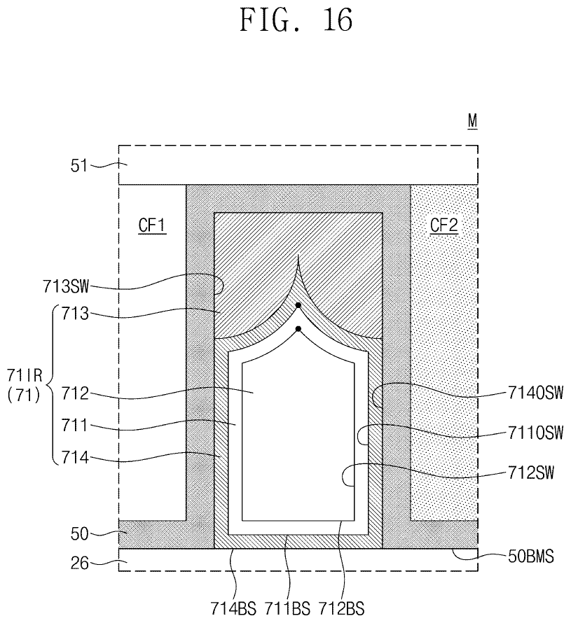

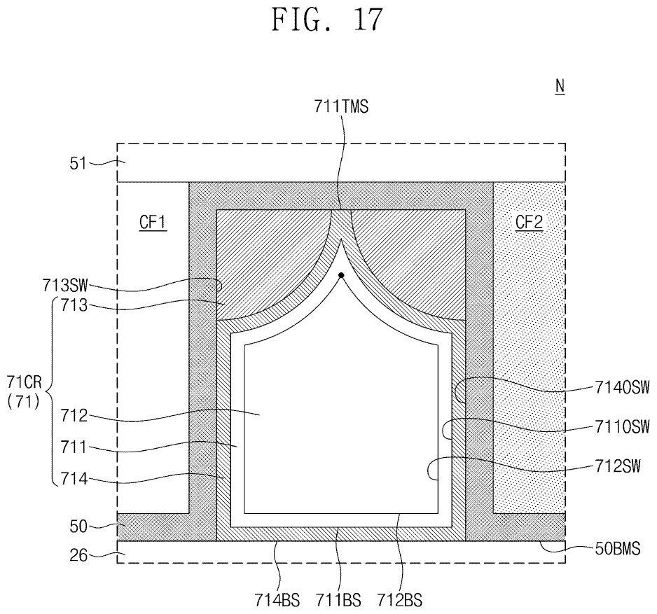

Referring to FIGS. 16 and 17, the grid structures 71 may further include a conductive line 714 that surrounds and is in contact with the gap insulating layer 711. An outer wall 7140SW of the conductive line 714 may be in contact with the capping layer 50, and an upper surface 714CTS of the conductive line 714 may be in contact with the supporter 713. The gap insulating layer 711 may be spaced apart from the supporter 713 and the capping layer 50 by the conductive line 714. The gap insulating layer 711 may be spaced apart from the backside insulating layer 26 by the conductive line 714.

An upper surface of the conductive line 714 may be in contact with the supporter 713 in the grid structure 71IR of the intervention region, and an upper surface of the conductive line 714 may be in contact with the supporter 713 and the capping layer 50 in the grid structure 71CR of the intersection region.

Differently from what is shown, an upper surface of the gap insulating layer 711 may also be in contact with the capping layer 50. In this case, the capping layer 50 may be in contact with the supporter 713, the upper surface of the gap insulating layer 711, and the upper surface of the conductive line 714.

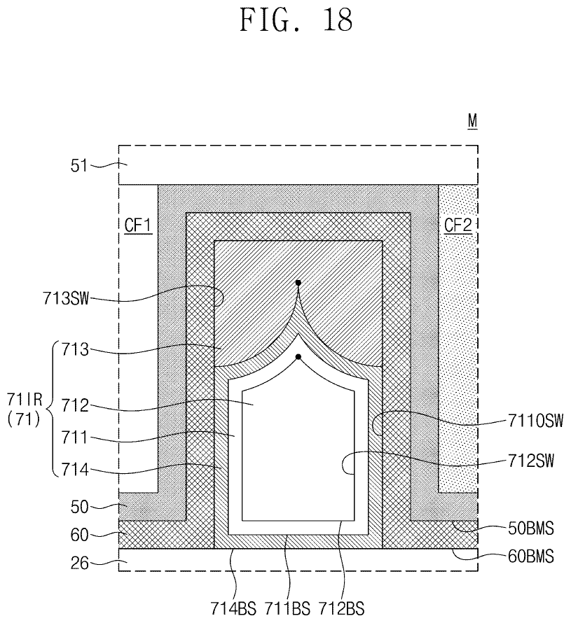

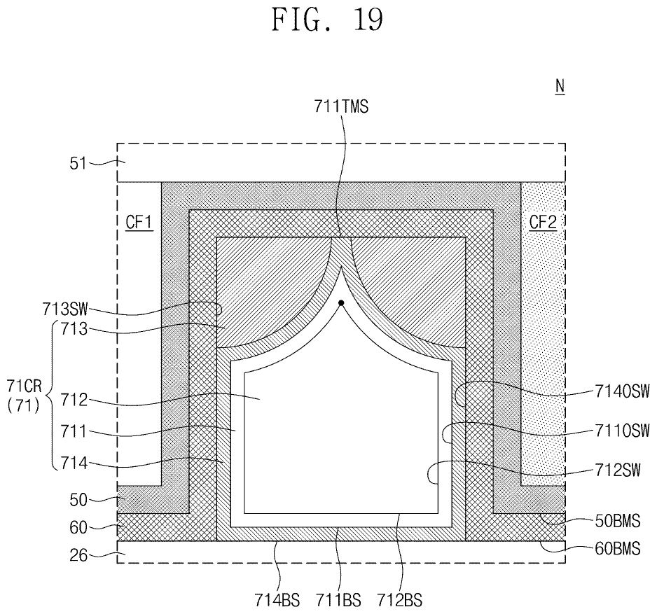

Referring to FIGS. 18 and 19, the grid structures 71 may further include a conductive line 714 that surrounds and is in contact with the gap insulating layer 711. A shield layer 60 may be provided below the capping layer 50. The capping layer 50 may be separated from the grid structures 71 by the shield layer 60.

The outer wall 714OSW of the conductive line 714 may be in contact with the shield layer 60, and the upper surface 714CTS of the conductive line 714 may be in contact with the supporter 713. The lower surface of the conductive line 714 may be in contact with the backside insulating layer 26. The gap insulating layer 711 may be separated from the supporter 713 and the capping layer 50 by the conductive line 714. The gap insulating layer 711 may be separated from the backside insulating layer 26 by the conductive line 714. The shield layer 60 may be in contact with the supporter, the conductive line 714, and the gap insulating layer 711.

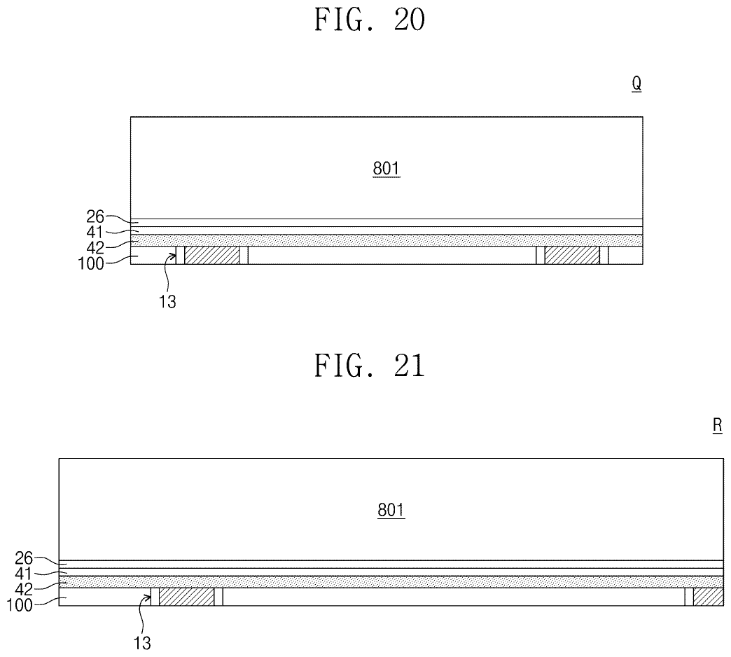

FIGS. 20, 22, 24, 26, 28, 30, 32, 34, 36, 38, 40, 42, 44, 46, 48 and 50 are enlarged views corresponding to the enlarged view of ‘Q’ in FIG. 2, which illustrate a method of fabricating an image sensor according to some embodiments of inventive concepts.

FIGS. 21, 23, 25, 27, 29, 31, 33, 35, 37, 41, 43, 45, 47, 49, 51 and 53 are enlarged views corresponding to the enlarged view of ‘R’ in FIG. 2, which illustrate a method of fabricating an image sensor according to some embodiments of inventive concepts.

Referring to FIGS. 20 to 31, a method of fabricating an image sensor according to the embodiments of FIGS. 2 to 5 is illustrated.

Referring to FIGS. 20 and 21, a fixed charge layer 42, a protective layer 41, and a backside insulating layer 26 may be prepared on a substrate 100 and a device separation pattern 13 having a structure described with reference to FIGS. 2 to 5. A patterning layer 801 may be formed on the backside insulating layer 26. The patterning layer 801 may include SOC, SOH, PR, or SiO2.

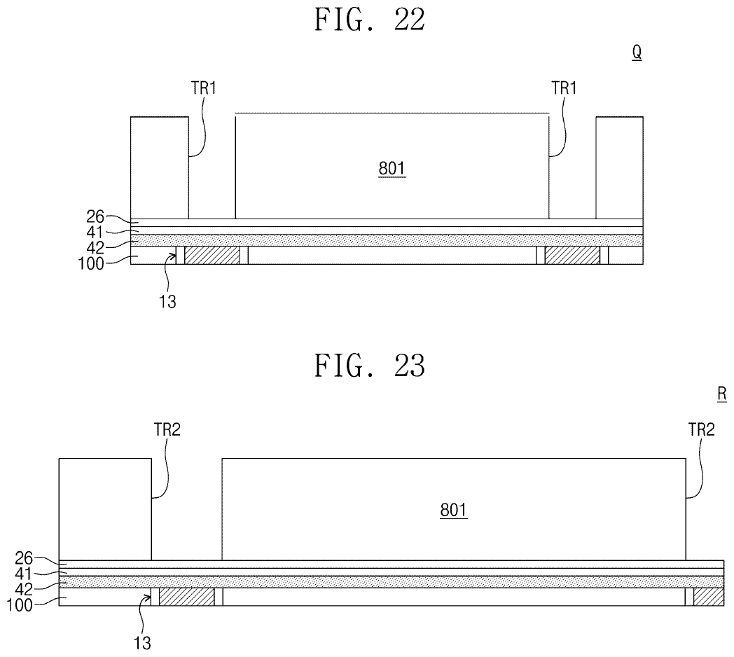

Referring to FIGS. 22 and 23, a portion of the patterning layer 801 where a grid structure will be formed later may be patterned to form a first trench TR1 and a second trench TR2. The first trench TR1 may be formed in a portion where a grid structure 71IR of an intervention region is to be formed, and the second trench TR2 may be formed in a portion where a grid structure 71CR of an intersection region is to be formed.

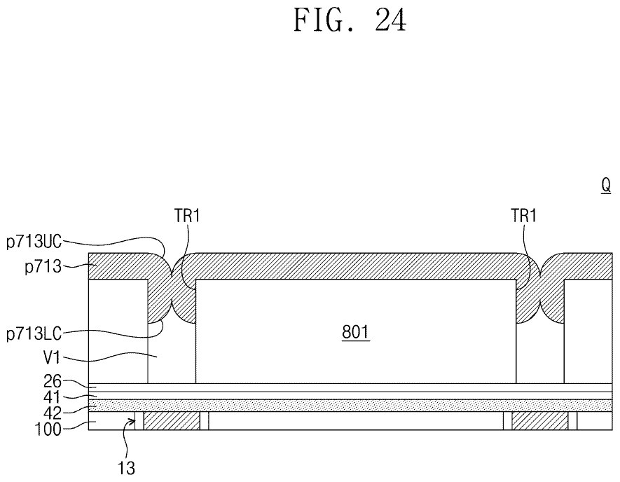

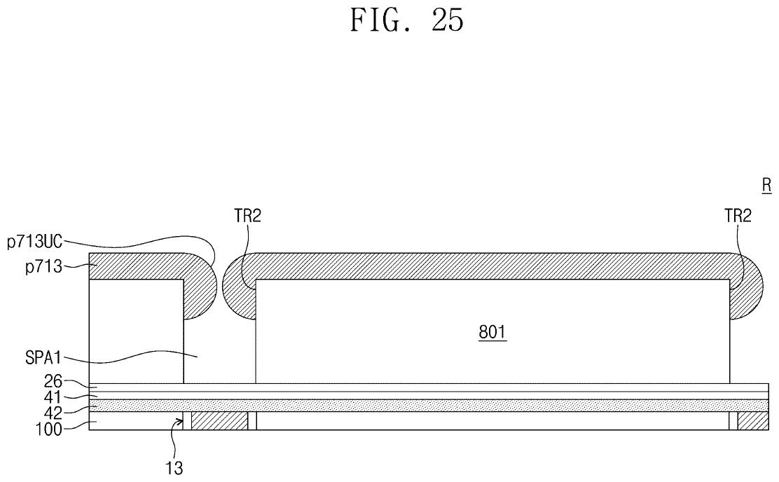

Referring to FIGS. 24 and 25, a preliminary support layer p713 may be formed. The preliminary support layer p713 may be formed on the patterning layer 801.

Referring to FIG. 24, in a portion where the grid structure 71IR of the intervention region is to be formed, the preliminary support layer p713 may be formed to cover an upper surface of the first trench TR1. Accordingly, the upper surface p713UC of the curved preliminary support layer p713 may be spaced apart from a lower surface p713LC of the curved preliminary support layer p713. A portion of the first trench TR1 may be filled with the preliminary support layer p713, and the unfilled portion may be defined as a first void V1.

Referring to FIG. 25, in a portion where the grid structure 71CR of the intersection region is to be formed, the preliminary support layer p713 may be formed not to cover the upper surface of the second trench TR2. In this case, a portion of the second trench TR2 may be filled with the preliminary support layer p713, thereby forming a first space SPA1 with an open upper portion. The exposed curved surface p713CB of the preliminary support layer p713 may form a non-separated integral body.

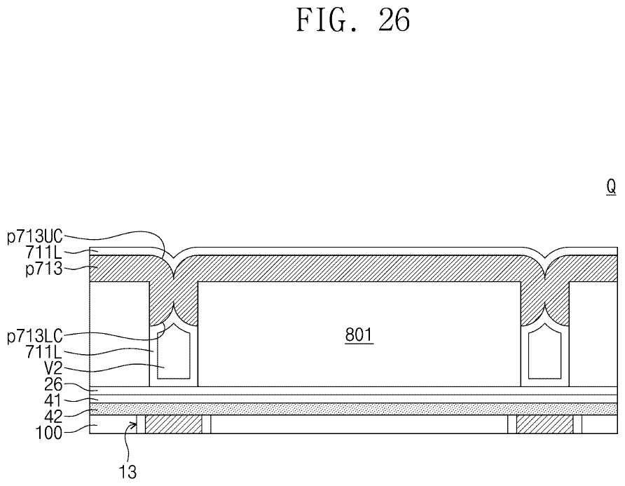

Referring to FIG. 26 and FIG. 27, a preliminary gap insulating layer 711L may be applied on the preliminary support layer p713. The preliminary gap insulating layer 711L may be formed through the first space SPA1 with the open upper portion in a portion where the grid structure 71CR of the intersection region is to be formed. For example, the preliminary gap insulating layer 711L may be formed by a low-temperature (process temperature 80 to 375° C.) process using an atomic layer deposition (ALD) process method with good step coverage.

As the preliminary gap insulating layer 711L is formed, a second void V2 may be formed in a portion where the grid structure 71IR of the intervention region is to be formed, and a third void V3 may be formed in a portion where the grid structure 71CR of the intersection region is to be formed.

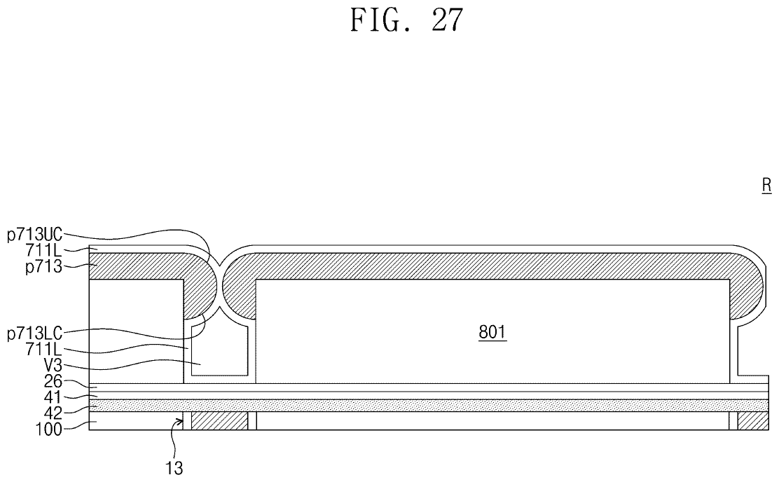

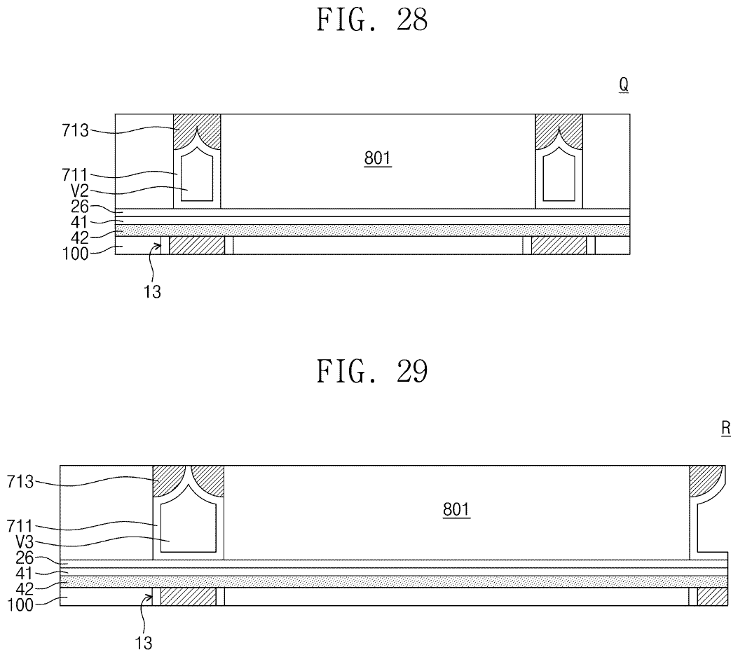

Referring to FIGS. 28 and 29, a portion of the preliminary support layer p713 and the preliminary gap insulating layer 711L may be removed. Accordingly, the supporter 713 and the gap insulating layer 711 may be formed.

Accordingly, the upper surface of the patterning layer 801 and the upper surface of the supporter 713 may be exposed in the portion where the grid structure 71IR of the intervention region is to be formed. The upper surface of the patterning layer 801, the upper surface of the supporter 713, and the upper surface of the gap insulating layer 711 may be exposed in the portion where the grid structure 71CR of the intersection region is to be formed.

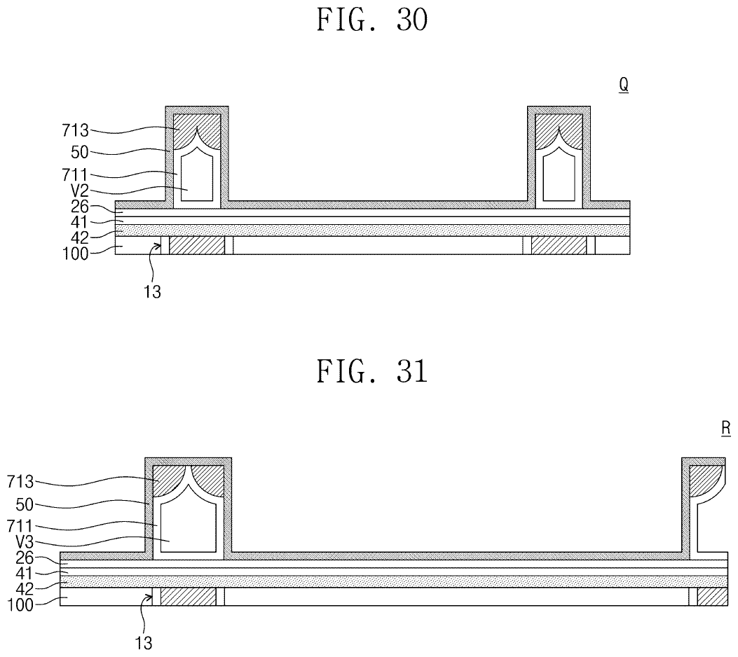

Referring to FIGS. 30 and 31, the patterning layer 801 may be removed. After the patterning layer 801 is removed, the capping layer 50 may be formed on the backside insulating layer 26. The capping layer 50 may be formed to cover the exposed backside insulating layer 26, the sidewall of the gap insulating layer 711, and the sidewall and upper surface of the supporter 713. The second void V2 and the third void V3 may form a fence gap 712.

Afterwards, a color filter CF is provided on the capping layer 50, and a backside protective layer 51 and a micro lens may be formed on the backside protective layer 51. The image sensor of FIGS. 1 to 5 may be formed.

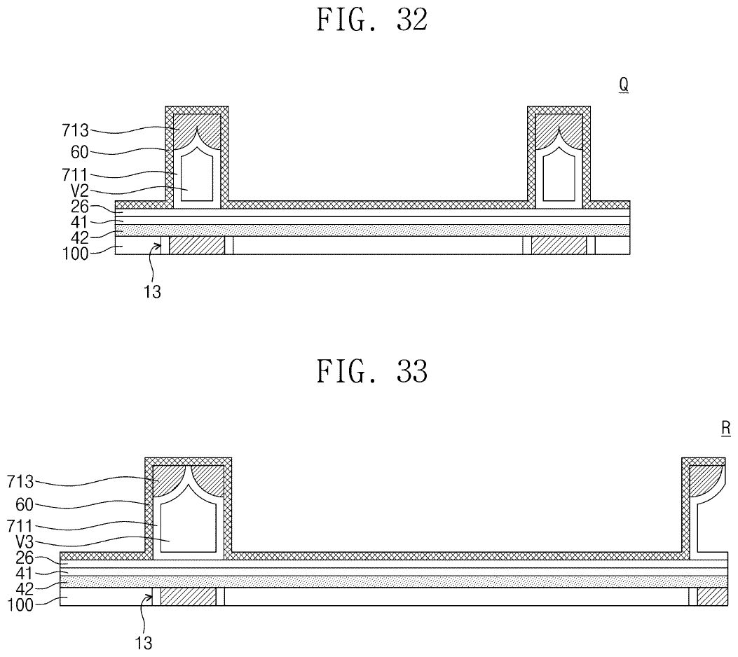

Referring to FIGS. 32 to 35, a fabricating method of an image sensor according to the embodiments of FIGS. 6 to 7 is shown. Before the processes of FIGS. 30 and 31, the processes up to FIG. 29 are performed in the same manner as above.

Referring to FIGS. 32 and 33, an upper surface of the patterning layer 801 and an upper surface of the supporter 713 may be exposed in a portion where the grid structure 71IR of the intervention region is to be formed. An upper surface of the patterning layer 801, an upper surface of the supporter 713, and an upper surface of the gap insulating layer 711 may be exposed in a portion where the grid structure 71CR of the intersection region is to be formed. Afterwards, the patterning layer 801 may be removed. After the patterning layer 801 is removed, a shield layer 60 may be formed on the backside insulating layer 26. The shield layer 60 may be formed to cover the exposed backside insulating layer 26, a sidewall of the gap insulating layer 711, and a sidewall and upper surface of the supporter 713. The second void V2 and the third void V3 may form a fence gap 712.

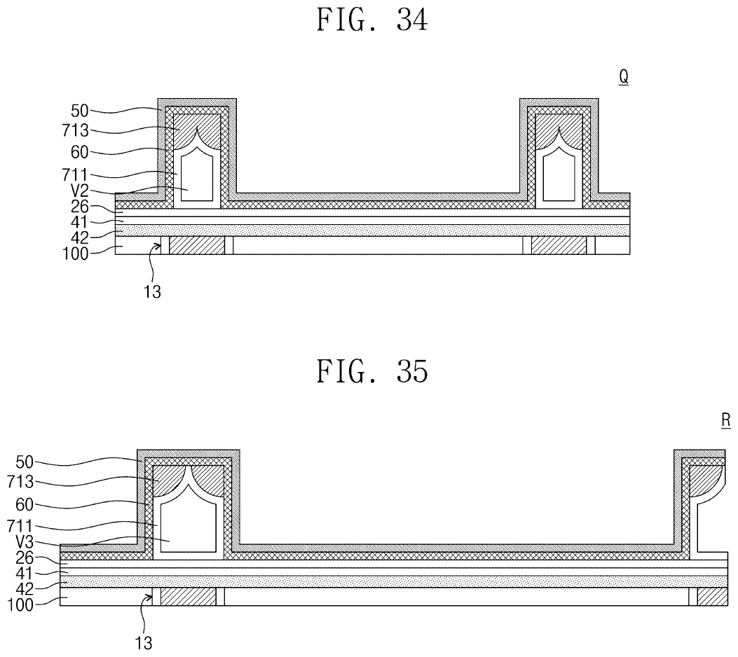

Referring to FIGS. 34 and 35, a capping layer 50 may be formed on the shield layer 60. The capping layer 50 may be formed to cover the entire shield layer 60. A color filter CF may be provided on the shield layer 60, and a micro lens may be formed on the backside protective layer 51. The image sensors of FIGS. 6 and 7 may be formed.

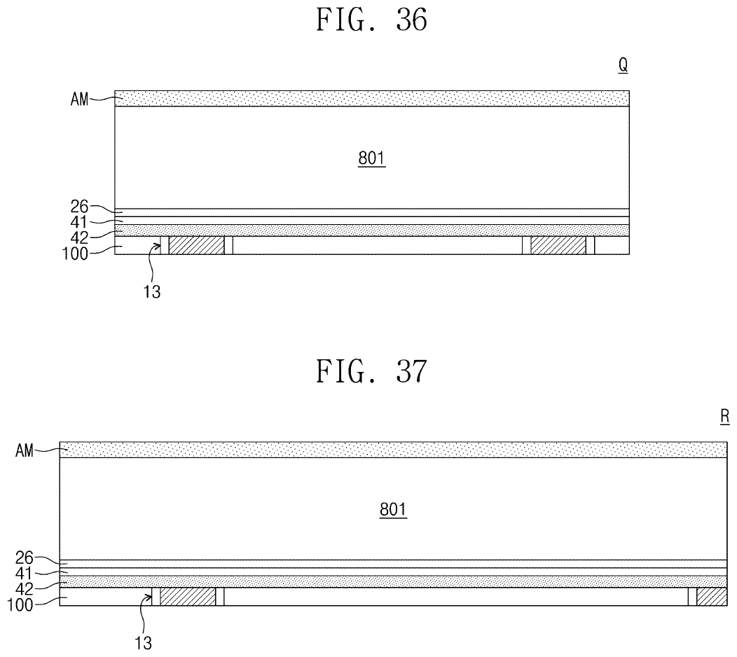

Referring to FIGS. 36 to 39, a method of fabricating an image sensor according to the embodiments of FIGS. 8 to 11 is shown.

Referring to FIGS. 36 and 37, a fixed charge layer 42, a protective layer 41, and a backside insulating layer 26 may be prepared on a substrate 100 and a device separation pattern 13. A patterning layer 801 may be formed on the backside insulating layer 26. An additional mask layer AM may be formed on the patterning layer 801.

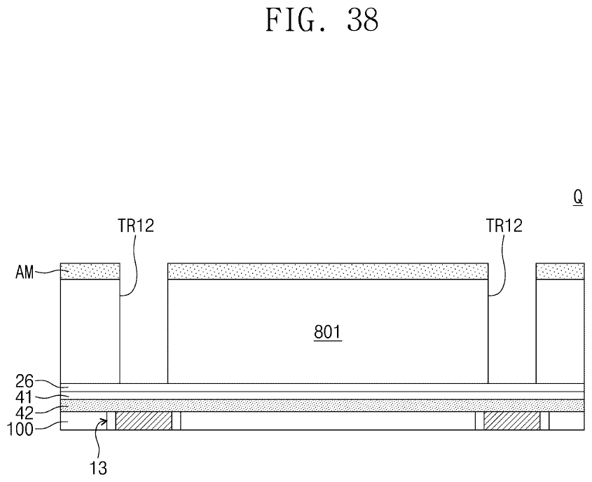

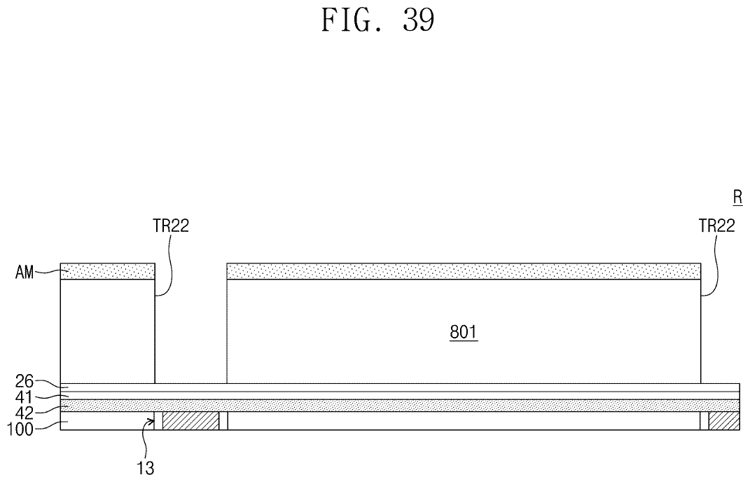

Referring to FIGS. 38 and 39, the patterning layer 801 and the additional mask layer AM may be patterned. A first extension trench TR12 and a second extension trench TR22 may be formed by the patterning layer 801 and the additional mask layer AM. The first extension trench TR12 and the second extension trench TR22 may be defined by a sidewall of the exposed patterning layer 801, a sidewall of the backside insulating layer 26, a sidewall of the protective layer 41, and an upper surface of the fixed charge layer 42. The first extension trench TR12 may be formed in a portion where the grid structure 71IR of the intervention region is to be formed, and the second extension trench TR22 may be formed in a portion where the grid structure 71CR of the intersection region is to be formed.

Thereafter, similar to the method of FIGS. 24 to 35, the image sensor of FIGS. 8 to 11 may be formed.

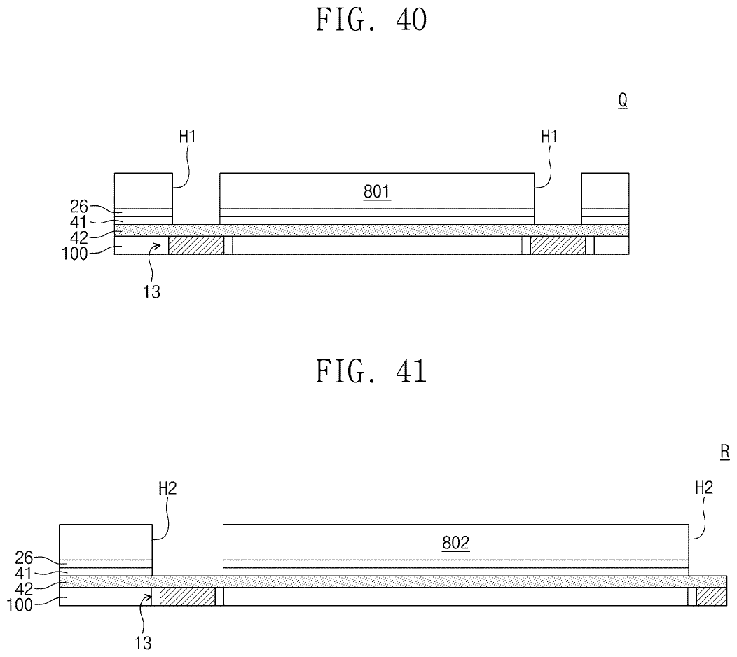

Referring to FIGS. 40 to 47, a method of fabricating an image sensor according to the embodiment of FIGS. 12 to 15 is shown.

Referring to FIGS. 40 and 41, a fixed charge layer 42, a protective layer 41, and a backside insulating layer 26 may be prepared on a substrate 100 and a device separation pattern 13. A pattern mask layer 802 may be formed on the backside insulating layer 26. The protective layer 41 and the backside insulating layer 26 may be etched by the pattern mask layer 802. As a result, a first hole H1 and a second hole H2 may be formed. The first hole H1 and the second hole H2 may be defined by the exposed sidewall of the protective layer 41, a sidewall of the backside insulating layer 26, and an upper surface of the fixed charge layer 42.

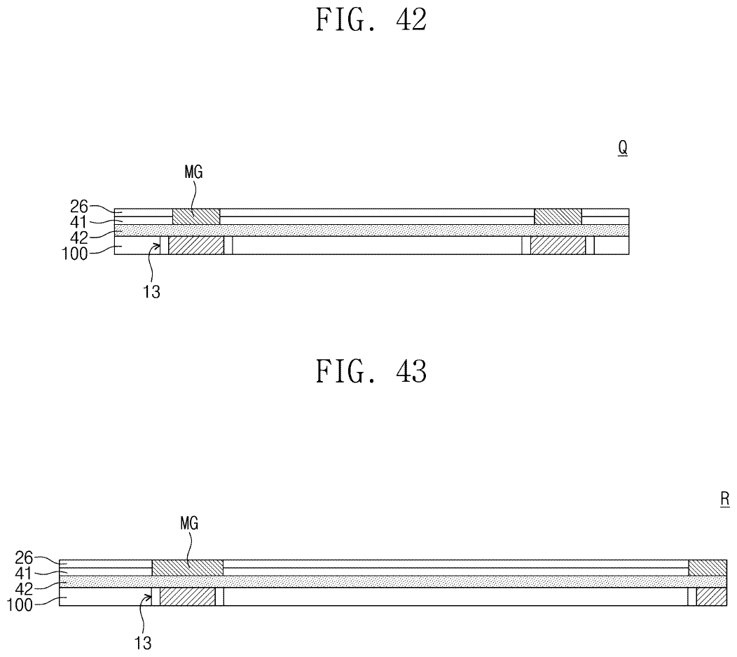

Referring to FIGS. 42 and 43, a conductive member MG may be formed to fill the first hole H1 and the second hole H2, and then the pattern mask layer 802 and an upper portion of the conductive member MG may be removed. This may expose the backside insulating layer 26. The conductive member MG may be left at the same level as the exposed backside insulating layer 26.

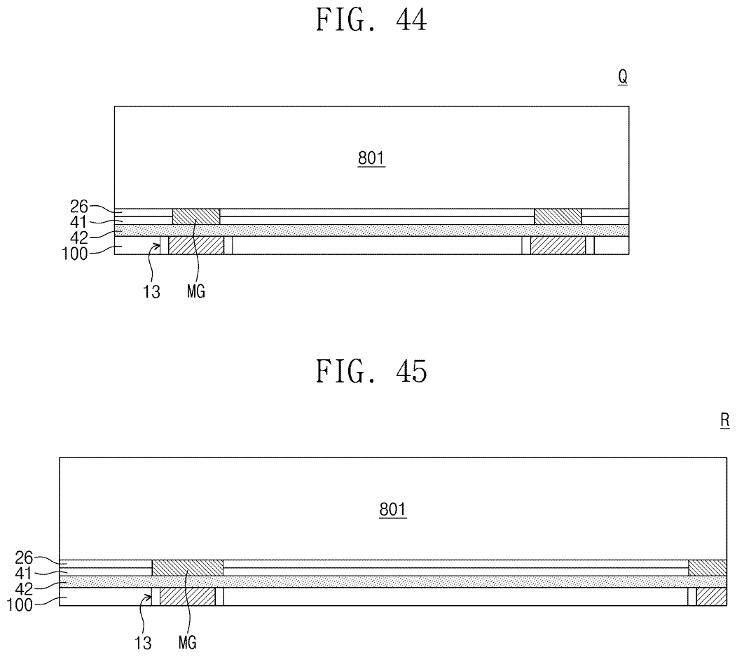

Referring to FIGS. 44 and 45, a patterning layer 801 may be formed on the backside insulating layer 26 and the conductive member MG. The patterning layer 801 may be formed to cover an upper surface of the conductive member MG and an upper surface of the backside insulating layer 26.

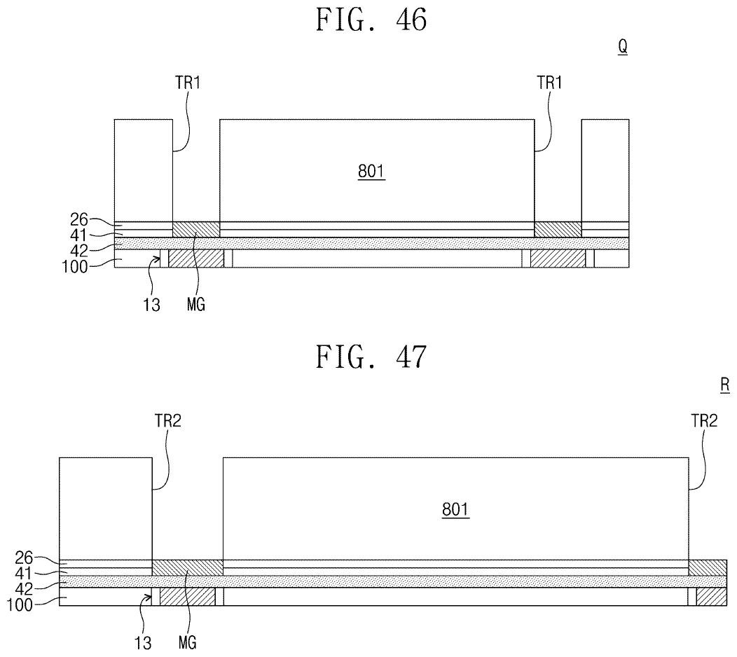

Referring to FIGS. 46 and 47, a first trench TR1 may be formed in a portion where a patterning layer 801 is patterned to form a grid structure 71IR of an intervention region, and a second trench TR2 may be formed in a portion where a grid structure 71CR of an intersection region is to be formed. Thereafter, similarly to the method of FIGS. 24 to 35, the image sensor of FIGS. 8 to 15 may be formed.

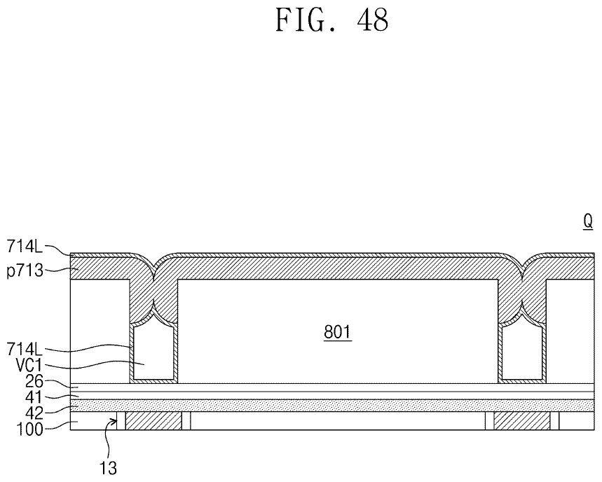

Referring to FIGS. 48 to 53, a method of fabricating an image sensor according to the embodiments of FIGS. 16 to 19 is shown.

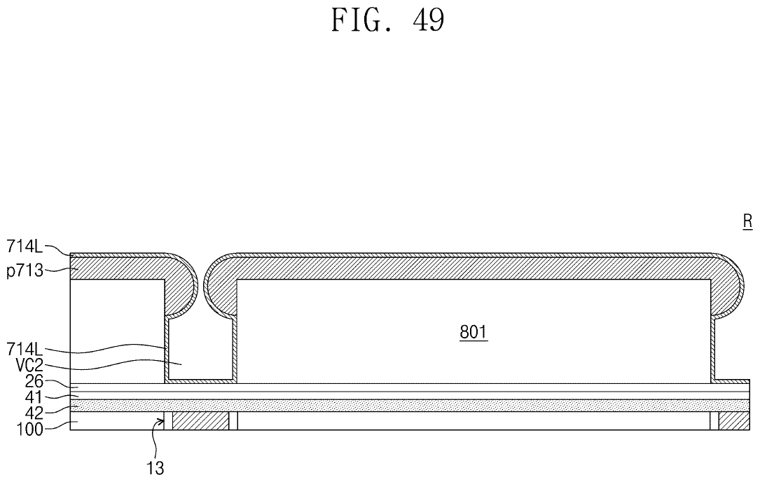

Referring to FIGS. 48 and 49, the processes of FIGS. 20 to 25 are performed in the same manner as above.

A preliminary conductive line 714L may be applied on a preliminary support layer p713. The preliminary conductive line 714L may be formed through an open upper space where the grid structure 71CR of the intersection region is to be formed.

By forming the preliminary conductive line 714L, a first vacancy VC1 surrounded by the preliminary conductive line 714L may be formed at a portion where the grid structure 71IR of the intervention region is to be formed, and a second vacancy VC2 may be formed by the preliminary conductive line 714L at a portion where the grid structure 71CR of the intersection region is to be formed.

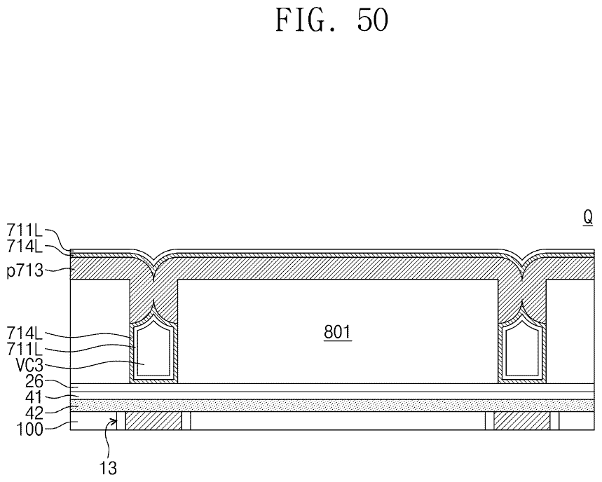

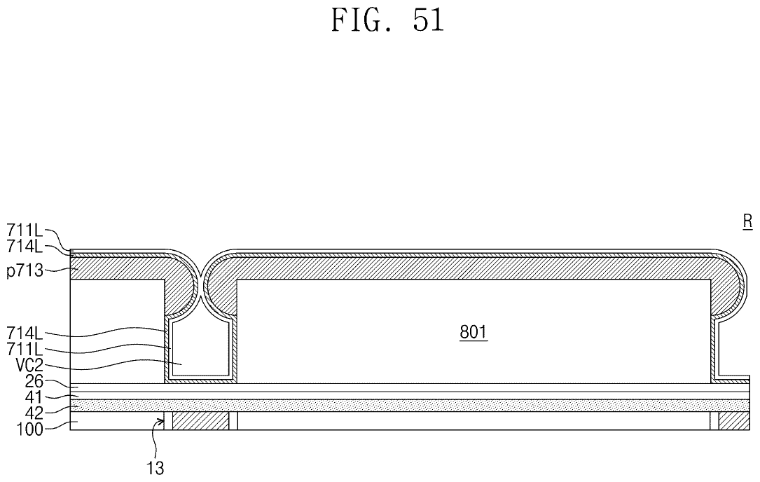

Referring to FIGS. 50 and 51, a preliminary gap insulating layer 711L may be formed on the preliminary conductive line 714L. By forming the preliminary gap insulating layer 711L at the portion where the grid structure 71CR of the intersection region is to be formed, it may be closed without the open space.

The preliminary gap insulating layer 711L may be formed through an open upper space where the grid structure 71CR of the intersection region is to be formed.

A third vacancy VC3 surrounded by the preliminary gap insulating layer 711L may be formed at a portion where the grid structure 71IR of the intervention region is to be formed.

A fourth vacancy VC4 surrounded by the preliminary gap insulating layer 711L may be formed at a portion where the grid structure 71CR of the intersection region is to be formed.

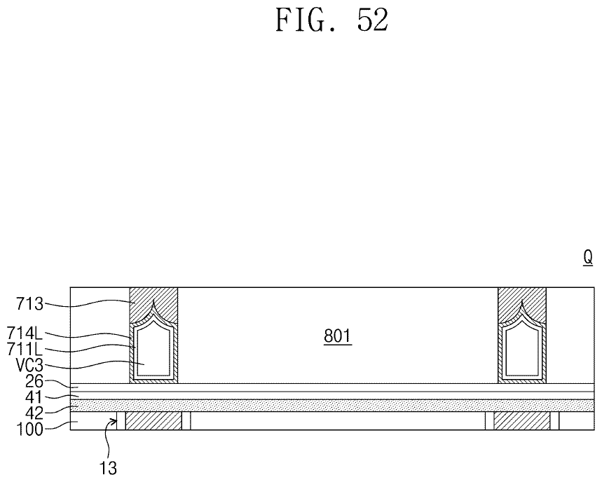

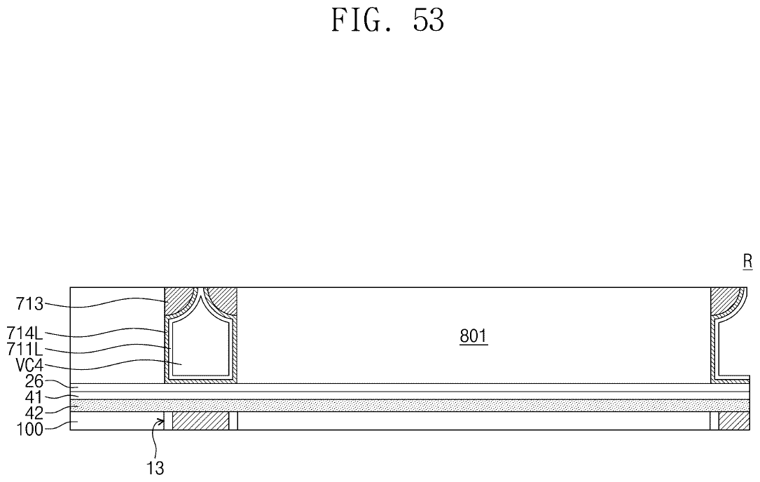

Referring to FIGS. 52 and 53, the preliminary support layer p713, the preliminary conductive line 714L, and the preliminary gap insulating layer 711L may be partially removed. Accordingly, the supporter 713 may be formed. The third vacancy VC3 and the fourth vacancy VC4 may form a fence gap 712. Thereafter, an image sensor according to the embodiments of FIGS. 16 to 19 may be formed through a process similar to that described above.

According to embodiments of inventive concepts, the image sensor may have the grid structure disposed between the color filters. In this case, the grid structure may include the grid gap therein. By the grid gap, the crosstalk of the image sensor may be reduced.

According to inventive concepts, the image sensor may have the grid structure disposed between the color filters. In this case, some of the grid structures may include the shield fence layer. This may improve the reliability and/or optical performance of the image sensor.

While embodiments are described above, a person skilled in the art may understand that many modifications and variations are made without departing from the spirit and scope of inventive concepts defined in the following claims. Accordingly, the example embodiments of inventive concepts should be considered in all respects as illustrative and not restrictive, with the spirit and scope of inventive concepts being indicated by the appended claims.

What is claimed is:

1. An image sensor comprising:
a semiconductor substrate in which a plurality of photoelectric converters are defined;
a plurality of color filters on the semiconductor substrate; and
grid structures between the plurality of color filters, respectively,
wherein the grid structures each include a gap insulating layer surrounding a fence gap defined by the gap insulating layer and a supporter on the gap insulating layer,
wherein the fence gap includes a gap upper curved surface, a first sidewall extending from the gap upper curved surface toward the semiconductor substrate, a second sidewall opposite the first sidewall, and a lower surface,
wherein the lower surface of the fence gap includes a flat surface between the first sidewall of the fence gap and the second sidewall of the fence gap,
wherein the gap insulating layer completely covers the gap upper curved surface of the fence gap, the first sidewall of the fence gap, and the second sidewall of the fence gap,
wherein the gap insulating layer covers 50% or more of the lower surface of the fence gap, and
wherein the supporter is spaced apart from the fence gap.

2. The image sensor of claim 1, wherein an upper surface of the gap insulating layer is in contact with the supporter and includes a gap insulating layer curved surface.

3. The image sensor of claim 2,
wherein a top point of the fence gap is defined as a gap top point,
wherein a level of the gap top point is higher than a level of a top point of the first sidewall of the fence gap, and
wherein the gap upper curved surface extends from the gap top point to the top point of the first sidewall of the fence gap.

4. The image sensor of claim 1, further comprising:
a capping layer surrounding an upper surface of a corresponding grid structure and a side surface of the corresponding grid structure, the corresponding grid structure being among the grid structures,
wherein a sidewall of the supporter and a sidewall of the gap insulating layer is in contact with the capping layer, and
wherein the capping layer is spaced apart from the fence gap.

5. The image sensor of claim 4, wherein a level of the lower surface of the fence gap is lower than a lowermost level of the capping layer.

6. The image sensor of claim 1, wherein the gap insulating layer covers 80% or more of the lower surface of the fence gap.

7. The image sensor of claim 1, further comprising:
a shield layer surrounding an upper surface of a corresponding grid structure and a side surface of the corresponding grid structure, the corresponding grid structure being among the grid structures; and
a capping layer on the shield layer, wherein
a level of the lower surface of the fence gap is lower than a lowermost level of the shield layer.

8. The image sensor of claim 1, wherein the gap insulating layer completely covers the lower surface of the fence gap.

9. The image sensor of claim 1, further comprising:
a fixed charge layer on the semiconductor substrate;
a protective layer on the fixed charge layer; and
a backside insulating layer on the protective layer,
wherein an outer wall of the gap insulating layer is in contact with the protective layer and the backside insulating layer.

10. An image sensor comprising:
a semiconductor substrate in which a plurality of photoelectric converters are defined;
a plurality of color filters on the semiconductor substrate; and
grid structures between the plurality of color filters, respectively,
wherein the grid structures include grid structures of an intervention region on the semiconductor substrate and grid structures of an intersection region on the semiconductor substrate,
wherein the grid structures of the intervention region and the grid structures of the intersection region each include a gap insulating layer surrounding a fence gap defined by the gap insulating layer and a supporter on the gap insulating layer,
wherein the fence gap includes a gap upper curved surface, a first sidewall extending from the gap upper curved surface toward the semiconductor substrate, a second sidewall opposite the first sidewall, and a lower surface,
wherein the lower surface of the fence gap includes a flat surface between the first sidewall of the fence gap and the second sidewall of the fence gap,
wherein the gap insulating layer completely covers the gap upper curved surface of the fence gap, the first sidewall of the fence gap, and the second sidewall of the fence gap,
wherein the gap insulating layer covers 50% or more of the lower surface of the fence gap, and
wherein the grid structures of the intersection region are spaced apart from each other.

11. The image sensor of claim 10, wherein
in the grid structures of the intervention region, the supporter is of integral form and spaced apart from the fence gap.

12. The image sensor of claim 10,
wherein a gap top point is defined by a top point of the fence gap at a level between a top surface of the supporter and a top surface of the second sidewall of the fence gap, and
wherein the gap insulating layer covers 80% or more of the lower surface of the fence gap.

13. The image sensor of claim 10, wherein
the grid structures of the intervention region and the grid structures of the intersection region each include a top surface of the gap insulating layer.

14. The image sensor of claim 10, further comprising:
a conductive member below the grid structures in the intervention region,
wherein the conductive member is between the semiconductor substrate and the gap insulating layer of the grid structures in the intervention region.

15. The image sensor of claim 10, further comprising:
a capping layer surrounding an upper surface and side surfaces of the grid structures of the intervention region and the grid structures of the intersection region, respectively,
wherein the grid structures of the intervention region and the grid structures of the intersection region each further include a conductive line that surrounding the gap insulating layer and in contact with the gap insulating layer.

16. The image sensor of claim 15, wherein, in the grid structures of the intervention region and the grid structures of the intersection region, respectively,
an outer wall of the conductive line is in contact with the capping layer, and
an upper surface of the conductive line is in contact with the supporter.

17. The image sensor of claim 10, wherein in the grid structures of the intervention region and the grid structures of the intersection region, respectively,
a lower surface of the supporter includes a curved surface, and
the supporter has a shape of a fan facing the fence gap.

18. An image sensor comprising:
a semiconductor substrate in which a plurality of photoelectric converters are defined, wherein a first surface of the semiconductor substrate is opposite a second surface of the semiconductor substrate;
a transfer gate on the first surface of the semiconductor substrate;
a fixed charge layer on the second surface of the semiconductor substrate;
a protective layer on the fixed charge layer;
a backside insulating layer on the protective layer;
a capping layer on the backside insulating layer;
a plurality of color filters on the capping layer; and
grid structures between the plurality of color filters, respectively,
wherein the grid structures each include a gap insulating layer surrounding a fence gap defined by the gap insulating layer and a supporter on the gap insulating layer,
wherein the fence gap includes a gap upper curved surface, a first sidewall extending from the gap upper curved surface toward the semiconductor substrate, a second sidewall opposite the first sidewall, and a lower surface,
wherein the lower surface of the fence gap includes a flat surface between the first sidewall of the fence gap and the second sidewall of the fence gap,
wherein the gap insulating layer completely covers the gap upper curved surface of the fence gap, the first sidewall of the fence gap, and the second sidewall of the fence gap,
wherein the gap insulating layer covers 50% or more of the lower surface of the fence gap, and
wherein the supporter is spaced apart from the fence gap.

19. The image sensor of claim 18,
wherein the grid structures further each include a conductive line surrounding the gap insulating layer,
wherein an outer wall of the conductive line is in contact with the capping layer, and
wherein an upper surface of the conductive line is in contact with the supporter.

20. The image sensor of claim 18, wherein the gap insulating layer includes one or more of Al₂O₃, SiO₂, TiO₂, Ta₂O₅, Ta₂O₃, HfO, ZrO, Si₃N₄, or SiCN.
